(19) United States
(12) Patent Application Publication
(10) Pub. No.: US 2024/0213107 A1
(43) Pub. Date: Jun. 27, 2024

(54) SEMICONDUCTOR DEVICE

(71) Applicant: Mitsubishi Electric Corporation, Tokyo (JP)

(72) Inventor: Hiroki HIDAKA, Tokyo (JP)

(73) Assignee: Mitsubishi Electric Corporation, Tokyo (JP)

(21) Appl. No.: 18/480,254

(22) Filed: Oct. 3, 2023

(30) Foreign Application Priority Data
Dec. 23, 2022 (JP) 2022-206612

(51) Int. Cl. H01L 23/053; H01L 23/10

(52) U.S. Cl. CPC H01L 23/053; H01L 23/10

(57) ABSTRACT

Provided is a semiconductor device with improved moisture resistance. A semiconductor device includes a semiconductor chip, a case, a sealing material arranged in the case and sealing the semiconductor chip, and a lid in close contact with the sealing material, wherein the case has at least one projection, the lid is provided with at least one first hole, and the at least one projection is in the at least one first hole, respectively, whereby the lid is fixed to the case.

### BACKGROUND OF THE INVENTION

### Field of the Invention

The present disclosure relates to a semiconductor device.

### Description of the Background Art

Japanese Patent Application Laid-Open No. 2021-111655 discloses a semiconductor device in which a lid is provided in such a manner as to be in contact with the upper surface of the sealing material in the inside of a case in order to improve moisture resistance.

In recent years, semiconductor devices have been used in many situations, such as for power generation, power transmission, and efficient use or regeneration of energy. In recent years, demand for moisture resistance in semiconductor devices has been growing.

However, the problem remains with the conventional technique, as it does not allow for sufficient improvement in moisture resistance.

### SUMMARY

An object of the present disclosure is to provide a semiconductor device with improved moisture resistance.

A semiconductor device includes a semiconductor chip, a case, a sealing material arranged in the case and sealing the semiconductor chip, and a lid in close contact with the sealing material. The case has at least one projection. The lid is provided with at least one first hole. The at least one projection is in the at least one first hole, respectively, whereby the lid is fixed to the case.

The present disclosure provides a semiconductor device with improved moisture resistance.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device according to Embodiment 1;

FIG. 2 is a plan view of a case of the semiconductor device according to Embodiment 1;

FIG. 3 is a cross-sectional view of a lid of the semiconductor device according to Embodiment 1;

FIG. 4 is a cross-sectional view of a semiconductor device according to Embodiment 2;

FIG. 5 is a plan view of a lid of the semiconductor device according to Embodiment 2;

FIG. 6 is a plan view of a lid of a semiconductor device according to Embodiment 3;

FIG. 7 is a plan view of a lid of a semiconductor device according to Embodiment 4;

FIG. 8 is a plan view of a case of a semiconductor device according to Embodiment 5; and

FIG. 9 is a plan view of a lid of the semiconductor device according to Embodiment 5.

### DESCRIPTION OF THE PREFERRED EMBODIMENTS

### A. Embodiment 1

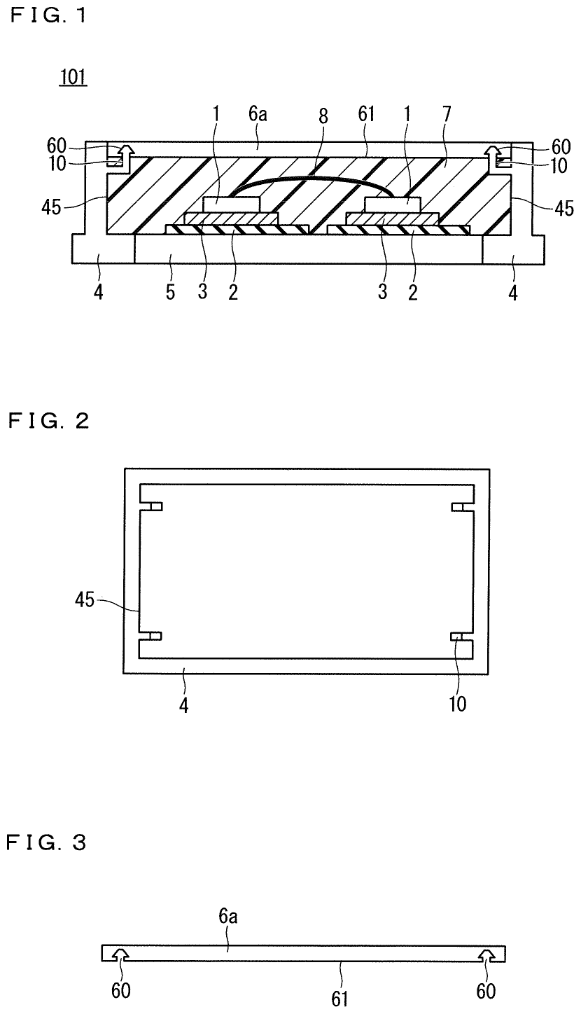

FIG. 1 is a cross-sectional view of a semiconductor device 101 according to Embodiment 1.

The semiconductor device 101 includes a semiconductor chip 1, an insulating layer 2, a metal pattern 3, a case 4, a base plate 5, a lid 6a, a sealing material 7, and wiring 8.

The material of the insulating layer 2 is ceramic or resin, for example. The insulating layer 2 is arranged on the base plate 5.

The metal pattern 3 is formed on the insulating layer 2.

The semiconductor chip 1 is arranged on the metal patterns 3. The semiconductor chip 1 is bonded onto the metal pattern 3 by soldering (not shown), for example.

Although two semiconductor chips 1 are shown in FIG. 1, the number of semiconductor chips included in the semiconductor device 101 may be one or three or more.

Two semiconductor chips 1 are connected by the wiring 8. The wiring 8 is, for example, a wire.

FIG. 2 is a plan view of the case 4. The case 4 has projections 10. The projections 10 are provided on an inner side surface 45 of the case 4, as shown in FIGS. 1 and 2.

The sealing material 7 is, for example, a sealing resin. The sealing resin is, for example, epoxy resin.

The semiconductor chips 1 are covered and protected by the sealing material 7 within the case 4.

The lid 6a is in close contact with the sealing material 7. The higher the adhesion between the lid 6a and the sealing material 7, the more the intrusion of moisture into the inside of the semiconductor device 101 can be suppressed, improving the moisture resistance.

FIG. 3 is a cross-sectional view of the lid 6a. As shown in FIGS. 1 and 3, the lid 6a is provided with holes 60. In the semiconductor device 101, the holes 60 are provided in a surface 61 of the lid 6a which is in close contact with the sealing material 7.

In the semiconductor device 101, the projections 10 are in the holes 60. The lid 6a is fixed to the case 4 by the projections 10 in the holes 60.

The sealing material 7 and the lid 6a are adhered to each other at the portion where the sealing material 7 and the lid 6a are in close contact with each other. For example, the sealing material 7 and the lid 6a are adhered to each other by curing the sealing material 7 while the sealing material 7 and the lid 6a are in close contact with each other in the manufacturing process.

The fixation of the lid 6a by the projections 10 may be any as long as the adhesion between the lid 6a and the sealing material 7 is enhanced by the fixation. The fixation may also be removable after inserting the projections 10 into the holes 60 in the manufacturing process.

For example, each projection 10 extends at the tip thereof in a direction intersecting the depth direction of the hole 60, and the lid 6a is thereby fixed by the projections 10.

For example, as shown in FIG. 1, the vicinity of the tip of the projection 10 has a frustoconical shape. The narrow side of the frustoconical shape is narrower than the opening of hole 60 and the wide side of the frustoconical shape is wider than the opening of hole 60. With this configuration, the projection 10 is fitted into the hole 60 by pressing the projection 10 into the hole 60.

Although FIG. 1 shows the case where the holes 60 are filled with the projections 10, the holes 60 may not be filled with the projections 10 as long as the lid 6a can be fixed by the projections 10.

The projections 10 in the holes 60 fix the lid 6a to the case 4 in a state in which the lid 6a and the sealing material 7 are in close contact with each other. Therefore, the semiconductor device 101 has higher moisture resistance than a case where the lid 6a is not fixed by the projections 10.

In the manufacturing process of the semiconductor device 101, for example, the sealing material 7 is cured after the lid 6a is attached to the case 4. The lid 6a being fixed to the case 4 by the projections 10 suppresses displacement of the lid 6a due to vibration of the curing furnace in the step of curing the sealing material 7.

### B. Embodiment 2

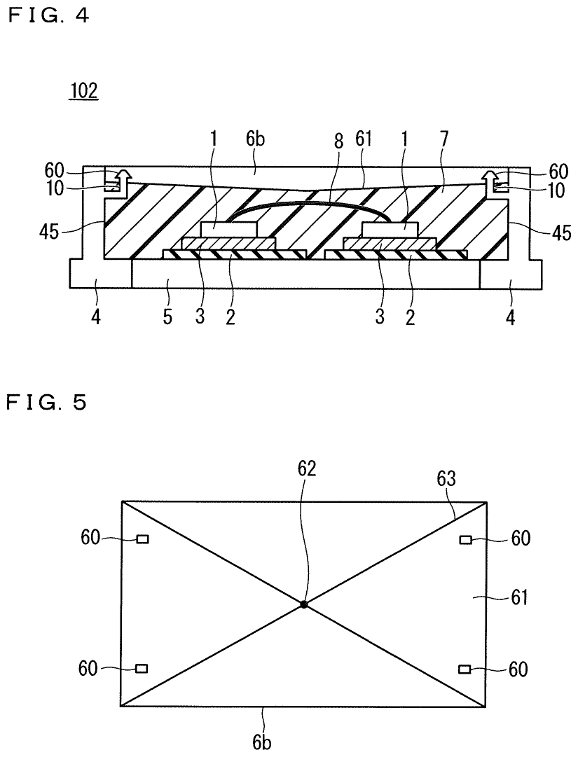

FIG. 4 is a cross-sectional view of a semiconductor device 102 according to Embodiment 2.

Compared with the semiconductor device 101 of Embodiment 1, the semiconductor device 102 includes a lid 6b instead of the lid 6a. In other respects, the semiconductor device 102 is similar to the semiconductor device 101.

As with the lid 6a, the lid 6b is provided with the holes 60.

As with the semiconductor device 101 of Embodiment 1, the projections 10 are in the holes 60 in the semiconductor device 102. The lid 6b is fixed to the case 4 by the projections 10 in the holes 60, with the lid 6b and the sealing material 7 being in close contact with each other. Therefore, the semiconductor device 102 has high moisture resistance.

As shown in FIG. 4, the surface 61 of the lid 6b which is in close contact with the sealing material 7 has a convex shape toward the sealing material 7.

FIG. 5 is a plan view of the lid 6b, and is a view of the lid 6b viewed from the side of the surface 61 in close contact with the sealing material 7. The surface 61 of the lid 6b, which is in close contact with the sealing material 7 is, for example, in the shape of a quadrangular pyramid with a point 62 as the apex, as shown in FIG. 5.

In the manufacturing process of the semiconductor device 102, the lid 6b is attached to the case 4 after the sealing material 7 is injected into the case 4, for example. Even if air bubbles are generated when the sealing material 7 is injected into the case 4, the convex portion of the surface 61 is pushed into the sealing material 7 when the lid 6b is attached to the case 4, which allows the air bubbles to escape easily. In a case where air bubbles remain between the lid 6b and the sealing material 7, they serve as paths for moisture to enter. The surface 61 having a convex shape toward the sealing material 7 suppresses residual air bubbles between the lid 6b and the sealing material 7, improving moisture resistance.

### C. Embodiment 3

Compared with the semiconductor device 102 of Embodiment 2, a semiconductor device of Embodiment 3 includes a lid 6c instead of the lid 6b. In other respects, the semiconductor device of Embodiment 3 is similar to the semiconductor device 102.

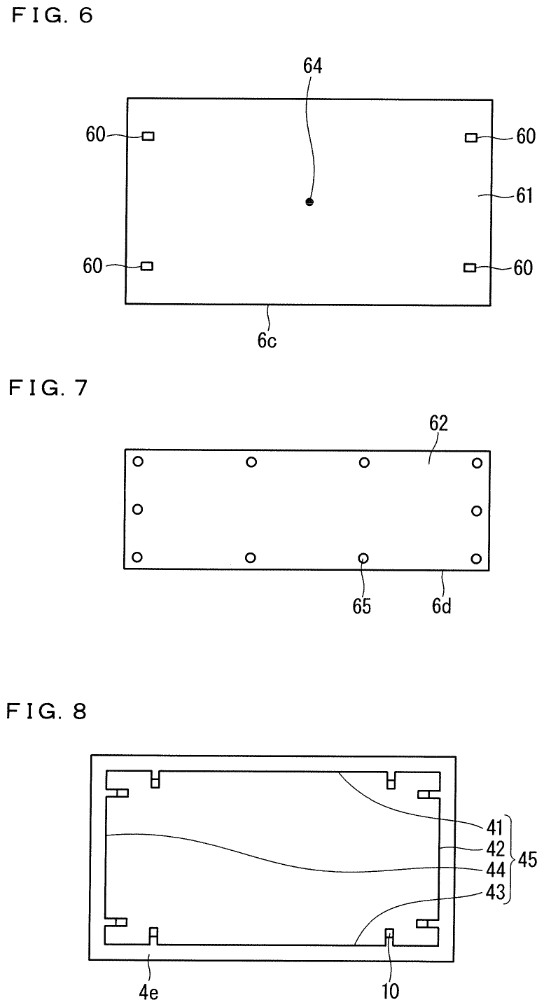

FIG. 6 is a plan view of the lid 6c, and is a view of the lid 6c viewed from the side of the surface 61 in close contact with the sealing material 7.

As in the case of the semiconductor device 101 of Embodiment 1, in the semiconductor device of Embodiment 3, the lid 6c is fixed to the case 4 by the projections 10 in the holes 60 with the lid 6c and the sealing material 7 being in close contact with each other. With this configuration, the semiconductor device of Embodiment 3 has high moisture resistance.

As with the lid 6b of Embodiment 2, the surface 61 of the lid 6c which is in close contact with the sealing material 7 has a convex shape toward the sealing material 7.

Regarding the lid 6b of Embodiment 2, sides 63 of the quadrangular pyramid shape of the surface 61 (see FIG. 5) are angular, whereas in the lid 6c, the surface 61 is a smooth curved surface between the apex 64 being a point located closest toward the sealing material 7 side and the outer circumference of the surface 61. The surface 61 of the lid 6c may also be smooth at the apex 64 or pointed at the apex 64. The lid 6c having a smooth curved surface between the apex 64 and the outer circumference of the surface 61 allows air bubbles generated when the sealing material 7 is injected into the case 4 in the manufacturing process to escape easily when the lid 6c is attached to the case 4.

### D. Embodiment 4

Compared with the semiconductor device 101 of Embodiment 1, a semiconductor device of Embodiment 4 includes a lid 6d instead of the lid 6d. In other respects, the semiconductor device of Embodiment 4 is similar to the semiconductor device 101.

FIG. 7 is a plan view of the lid 6d, and is a diagram viewed from the side of a surface 62 opposite to the surface in close contact with the sealing material 7.

As with the lid 6a, the lid 6d has the holes 60 on the side opposite to the surface 62.

In the semiconductor device of Embodiment 4, the lid 6d is fixed to the case 4 by the projections 10 in the holes 60 with the lid 6d and the sealing material 7 being in close contact with each other. With this configuration, the semiconductor device of Embodiment 4 has high moisture resistance.

Holes 65 extending from the surface in close contact with the sealing material 7 to the surface 62 opposite to the surface are provided at the end portion of the lid 6d in plan view.

By providing the holes 65 in the lid 6d, the air between the sealing material 7 and the lid 6d can escape easily in the manufacturing process. With this configuration, the adhesion between the sealing material 7 and the lid 6d is further enhanced, further improving the moisture resistance of the semiconductor device of Embodiment 4.

If the holes 65 are situated at the end portion of the lid 6d, this makes most of the surface of the sealing material 7 on the lid 6d side in contact with the lid 6d. Therefore, the provision of the holes 65 does not lower a much degree of moisture resistance of the semiconductor device of Embodiment 4.

The surface of the lid 6d in close contact with the sealing material 7 may have a convex shape toward the sealing material 7, as with the lid 6b or the lid 6c of Embodiment 2 or 3.

### E. Embodiment 5

Compared with the semiconductor device 101 of Embodiment 1, the semiconductor device of Embodiment 5 includes a case 4e instead of the case 4. Compared with the semiconductor device 101 of Embodiment 1, the semiconductor device of Embodiment 5 includes a lid 6e instead of the lid 6a. In other respects, the semiconductor device of Embodiment 5 is similar to the semiconductor device 101. FIG. 8 is a plan view of the case 4e.

An inner side surface 45 of the case 4e has a surface 41, a surface 42, a surface 43, and a surface 44 separated by sides.

As shown in FIG. 8, projections 10 are provided on each of the surface 41, the surface 42, the surface 43, and the surface 44 of the case 4e.

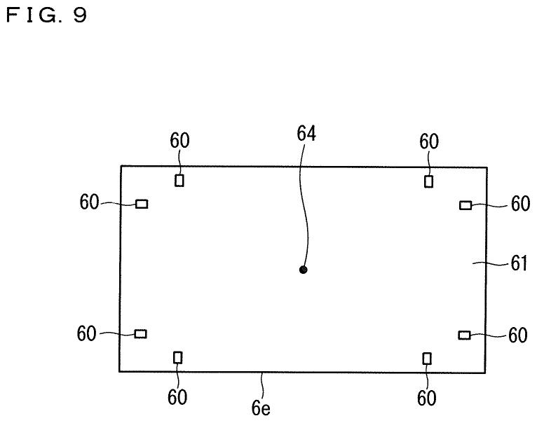

FIG. 9 is a plan view of the lid 6e, and is a view of the lid 6e viewed from the side of the surface 61 in close contact with the sealing material 7. The lid 6e is provided with the holes 60 corresponding to the projections 10 provided on the surface 41, the surface 42, the surface 43, and the surface 44, respectively.

In the semiconductor device of Embodiment 5, the projections 10 provided on the surface 41, the surface 42, the surface 43, and the surface 44 are each inserted into the holes 60 of the lid 6e. Thereby, the lid 6e is fixed to the case 4e with the lid 6e and the sealing material 7 being in close contact with each other.

With the projections 10 being provided on each of the surface 41, the surface 42, the surface 43, and the surface 44 of the inner side surface 45 of the case 4e, the more accurate fixing position of the lid 6e is ensured. And this secures much better suppression of the displacement of the lid 6e.

It should be noted that Embodiments can be arbitrarily combined and can be appropriately modified or omitted.

Hereinafter, the aspects of the present disclosure will be collectively described as Appendices.

### Appendix 1

A semiconductor device comprising:
a semiconductor chip;
a case;
a sealing material arranged in the case and sealing the semiconductor chip; and
a lid in close contact with the sealing material, wherein
the case has at least one projection,
the lid is provided with at least one first hole, and
the at least one projection is in the at least one first hole, respectively, whereby the lid is fixed to the case.

### Appendix 2

The semiconductor device according to Appendix 1, wherein
the at least one first hole is provided on a surface of the lid that is in close contact with the sealing material.

### Appendix 3

The semiconductor device according to Appendix 1 or 2, wherein
the surface of the lid in close contact with the sealing material is convex toward the sealing material.

### Appendix 4

The semiconductor device according to Appendix 3, wherein
the surface of the lid in close contact with the sealing material is a smooth curved surface between a point located closest toward the sealing material side and an outer circumference of the surface of the lid in close contact with the sealing material.

### Appendix 5

The semiconductor device according to any one of Appendices 1 to 4, wherein
a second hole extending from a surface in close contact with the sealing material to a surface opposite to the surface in close contact with the sealing material is provided at an end portion of the lid in plan view.

### Appendix 6

The semiconductor device according to any one of Appendices 1 to 5, wherein
the at least one projection is a plurality of projections,
an inner side surface of the case has a plurality of surfaces separated by sides, and
each of the plurality of surfaces is provided with any of the plurality of projections.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor chip;
a case;
a sealing material arranged in the case and sealing the semiconductor chip; and
a lid in close contact with the sealing material, wherein
the case has at least one projection,
the lid is provided with at least one first hole, and
the at least one projection is in the at least one first hole, respectively, whereby the lid is fixed to the case.

2. The semiconductor device according to claim 1, wherein
the at least one first hole is provided on a surface of the lid that is in close contact with the sealing material.

3. The semiconductor device according to claim 1, wherein
the surface of the lid in close contact with the sealing material is convex toward the sealing material.

4. The semiconductor device according to claim 3, wherein
the surface of the lid in close contact with the sealing material is a smooth curved surface between a point located closest toward the sealing material side and an outer circumference of the surface of the lid in close contact with the sealing material.

5. The semiconductor device according to claim 1, wherein
a second hole extending from a surface in close contact with the sealing material to a surface opposite to the surface in close contact with the sealing material is provided at an end portion of the lid in plan view.

6. The semiconductor device according to claim 1, wherein
the at least one projection is a plurality of projections,
an inner side surface of the case has a plurality of surfaces separated by sides, and
each of the plurality of surfaces is provided with any of the plurality of projections.
